(19) United States
(12) Patent Application Publication
(10) Pub. No.: US 2015/0357548 A1
(43) Pub. Date: Dec. 10, 2015

(54) METHOD FOR FORMING A THERMOELECTRIC FILM HAVING A MICRO GROOVE

(71) Applicant: NATIONAL CENTRAL UNIVERSITY, JHONGLI CITY (TW)

(72) Inventors: Sheng-Wei LEE, TAIPEI CITY (TW); Yi-Fan NIU, JHONGLI CITY (TW); Pei-Wen LI, JHONGLI CITY (TW); Cheng-Lun HSIN, JHONGLI CITY (TW); Chung-Jen TSENG, JHONGLI CITY (TW)

(21) Appl. No.: 14/334,447

(22) Filed: Jul. 17, 2014

(30) Foreign Application Priority Data
Jun. 9, 2014 (TW) 103119878

(51) Int. Cl. H01L 35/34

(52) U.S. Cl. CPC H01L 35/34

(57) ABSTRACT

A method for forming a thermoelectric film having a micro groove includes the following steps: A) forming a plurality of parallel sacrificing wires by electrospinning, a diameter of each sacrificing wire being 100-500 nm; B) coating a thermoelectric film having a thickness of 80-200 nm on a part of a surface of each sacrificing wire; and C) removing the sacrificing wires from the thermoelectric films and thus obtaining the thermoelectric films each having the micro groove, a radio side of each thermoelectric film being open to the surroundings. The thermoelectric films finally prepared can have higher size uniformity without the disadvantage of catalyst residual. Further, the thermoelectric films each have a size smaller than the mean free path of phonons in one dimension, and thus the thermoelectric properties of the thermoelectric films can be improved.

### BACKGROUND OF THE INVENTION

1. Field of the Invention

The present invention relates generally to a method of forming a thermoelectric film, and more specifically to a method of forming a thermoelectric film having a micro groove.

2. Description of the Related Art

Fossil fuels are currently the primary sources of energy consumption in the world. Owing to the nonrenewable characteristics of fossil fuels, people are dedicated to find other renewable energies and to reuse waste energies such as waste heat including industrial heat, vehicle-emitted heat and environmental heat. If these waste heat can be reused properly, the dependency on fossil fuels can be lowered and the consumption of fossil fuels can be mitigated.

Some thermoelectric materials have been recognized and can convert heat energy into electricity directly. If the thermoelectric material has a size smaller than the mean free path of phonons and larger than that of the electrons in one or more dimensions, its thermal conductivity can be reduced without sacrificing electrical conductivity thereof. Thus the ZT value can be increased, and the thermoelectric material can covert heat energy into electricity more efficiently.

In order to prepare a thermoelectric material whose size satisfies the above-mentioned conditions, Marolop Simanullang et al. utilize a vapor-liquid-solid method, which incorporates the introduction of catalysed second phase material for the growth of one-dimensional structures. To do so, a liquid droplet (liquid phase) of the catalyst itself or an alloy of the catalyst and a substance to be grown is prepared, the substance to be grown (vapor phase) is then absorbed on the liquid surface, and thereafter the substance is condensed on the substrate, leading to an one-dimensional-growing structure (solid phase). The drawback of such VLS method is that there will be nano-scaled catalyst residual remained on the tips on the grown nano wire.

C. Fang et al., on the other hand, discloses an electrochemically etching method. Noble metal is placed on a substrate as a catalyst. Metal ions in the solution extracts electrons from a semi-conductor and forms nano metal particles, and then hydrogen fluoride is used to continuously etch the substrate oxide beneath the nano metal particles. A nano wire matrix can be prepared thereby. However, due to the poor size uniformity of the nano metal particles, the diameters of the individual nano wires can vary in a wild range.

Therefore, it is desirable for one skilled in the art to prepare a catalyst residual free thermoelectric material having a highly-uniformed size that is smaller than the mean free path of phonons in one dimension.

### SUMMARY OF THE INVENTION

It is a main objective of the present invention to provide a method of forming a thermoelectric film having a micro groove, in which the thermoelectric film is formed without catalyst residual and has high diameter uniformity.

To achieve the above and other objectives of the present invention, a method of forming a thermoelectric film having a micro groove is provided. The method includes the following steps:

A) forming a plurality of parallel sacrificing wires by electrospinning, a diameter of each sacrificing wire being 100-500 nm;

B) coating a thermoelectric film having a thickness of 80-200 nm on a part of a surface of each sacrificing wire; and

C) removing the sacrificing wires from the thermoelectric films and thus obtaining the thermoelectric films each having the micro groove, a radio side of each thermoelectric film being open to the surroundings.

The prepared thermoelectric films have micro grooves having uniform diameters because the initially formed sacrificing wires are highly uniform in diameter. Further, there will be no catalyst remained on the thermoelectric film in the present invention, and therefore the prepared thermoelectric films can have desirable thermoelectric properties adapted for later tests and applications.

### BRIEF DESCRIPTION OF THE DRAWINGS

The present invention can be understood more fully by referring to the detailed description below, as well as the accompanying drawings. However, it must be understood that both the descriptions and drawings are given by way of illustration only, and thus do not limit the present invention

FIG. 1 is a flow chart of the present invention;

FIGS. 2 is a schematic drawing showing the preparation of a thermoelectric film;

FIG. 3 is a schematic drawing more specifically showing the preparation of a thermoelectric film in a preferred embodiment of the present invention;

FIG. 4 is an SEM image showing the thermoelectric film formed by the method in accordance with the preferred embodiment of the present invention.

### DETAILED DESCRIPTION OF THE INVENTION

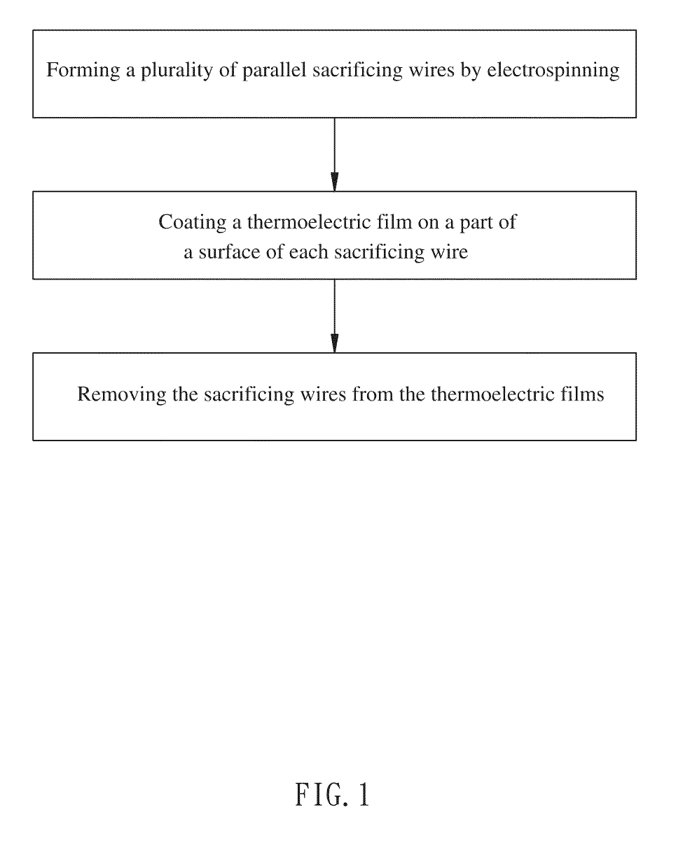

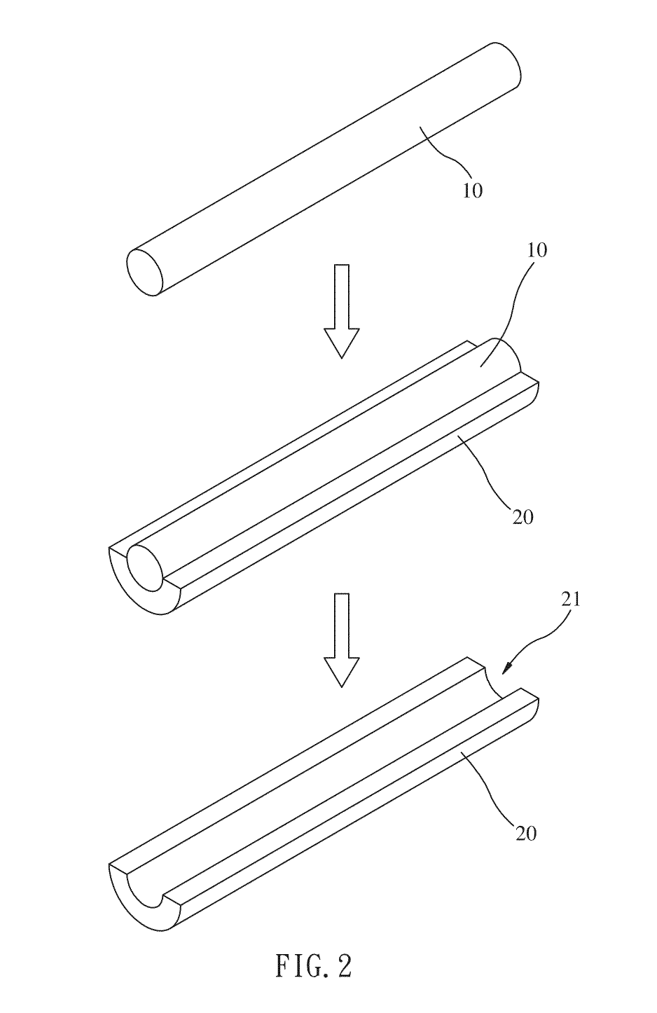

Please refer to FIGS. 1 and 2. The present invention provides a method of forming a thermoelectric film 20 having a micro groove 21. The thermoelectric film 20 has a radio side open to the surroundings. In other words, the thermoelectric film 20 is laterally open on one side and does not form a tube. The method of forming the thermoelectric film includes the following steps:

A) forming a plurality of parallel sacrificing wires 10 by electrospinning. A diameter of each sacrificing wire 10 is 100-500 nm. If the diameter of the sacrificing wire 10 were smaller than 100 nm, the sacrificing wire 10 might not be made easily. If the diameter thereof were bigger than 500 nm, the thermoelectric properties of later formed thermoelectric film 20 could not be efficiently improved. The aforementioned electrospinning is a means using an electrical charge to draw fine fibers from a liquid. During electrospinning, high voltage is applied to a metal needle filled with sacrificing material, the sacrificing material is then ejected from the needle and meanwhile charged, and then the sacrificing material is stretched and collected by a collecting electrode. To efficiently collect the sacrificing wires 10, the collecting electrode is preferably a grounded metal plate 30 having a longitudinal slot 31 formed thereon, so that the sacrificing wires 10 can span the longitudinal slot 31 laterally and parallel to each other due to the electric field across the longitudinal slot 31. Sacrificing materials applicable to electrospinning includes but not limited to polymers such as polyvinylpyrrolidone (PYP), polyvinyl alcohol (PVA), polyvinyl acetate (PVAc), poly(methyl methacrylate) (PMMA), polystyrene (PS) and polyacrylonitrile (PAN).

B) coating a thermoelectric film 20 having a thickness of 80-200 nm on a part of a surface of each sacrificing 10. The means to coat thermoelectric material on the sacrificing wire 10 can be coating methods that does not damage the sacrificing wire 10, and the coating methods includes but not limited to physical vapor deposition processes such as electron gun evaporation process. Thermoelectric materials applicable to the present invention includes but not limited to germanium, silicon, bismuth telluride, lead telluride, alloys thereof and other material having adequate thermoelectric properties. The thermoelectric film 20 has a thickness of 80-200 nm in radial direction. If the thickness were lower than the prior range, the mechanical strength might be too low. If the thickness were higher than the prior range, the desirable thermoelectric properties might not be obtained.

C) removing the sacrificing wires 10 from the thermoelectric films 20 and thus obtaining the thermoelectric films 20 each having the micro groove 21, while the thermoelectric films 20 are laterally open. That is, the thermoelectric films 20 are shell-like rather than tube-like. Thereby, each thermoelectric film 20 has an inner diameter and thickness both smaller than the mean free path of phonons in the radial direction. Also, the prepared thermoelectric films 20 each have a substantially arced profile. And thus each thermoelectric film 20 has a substantially half-rounded contour line which defines the micro groove. The term “micro groove” refers to a groove having a diameter smaller than 1 micron and does not exceed the diameter of the sacrificing wire 10. The way to remove the sacrificing wires 10 includes but not limited to processes that can remove only the sacrificing material but not the thermoelectric material, such as dissolving and annealing.

The thermoelectric films prepared by the aforementioned method can have higher size uniformity without the disadvantage of catalyst residual. In addition, the thermoelectric films each have a size smaller than the mean free path of phonons in one dimension, i.e. the radial direction. Taking germanium or silicon as an example, the mean free path of phonons thereof is about 1000 nm. Therefore, the prepared thermoelectric films can have better thermoelectric properties.

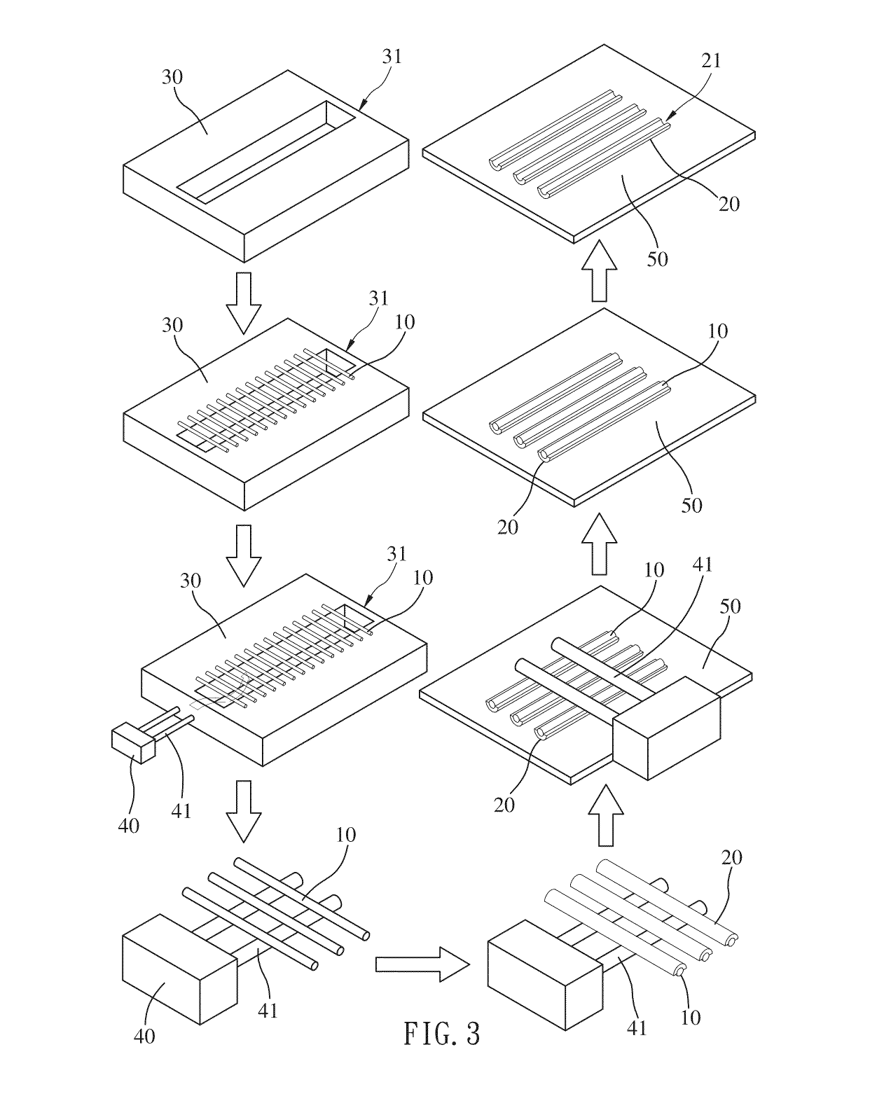

Referring to FIG. 3 for a preferred embodiment of the present invention. Thermoelectric films are prepared by the following steps:

A) using PVP as a sacrificing material. Preparing mixtures of ethanol and 5 wt %, 9 wt % and 13 wt % of PVP respectively. Stirring the mixtures by a magnetic stirrer to form homogeneous solutions. Using the homogeneous solutions respectively to electrospin a plurality of parallel sacrificing wires 10. The sacrificing wires 10 are collected by a grounded copper plate 30 having a longitudinal slot 31, so that the sacrificing wires 10 can span the longitudinal slot 31 laterally. The diameter of sacrificing wires 10 made from the homogeneous solution containing 5 wt % of PVP is about 100 nm. The diameter of sacrificing wires 10 made from the homogeneous solution containing 9 wt % of PVP is about 300 nm. The diameter of sacrificing wires 10 made from the homogeneous solution containing 13 wt % of PVP is about 500 nm.

A2) Due to the hydrolysable feature of PVP, the sacrificing wires 10 are recollected from the metal plate 30 by a collector 40 having two collecting bars 41 and stored properly. A distance between the collecting bars 41 is smaller than a width of the longitudinal slot 31 such that the collecting bars 41 can insert in the longitudinal slot 31 and collect the sacrificing wires 10 from inside. The collecting bars 41 are preferably coated with adhesive such that when the sacrificing wires 10 disengage with the metal plate 30, the sacrificing wires 10 can be adhered to the collecting bars 41 and remain parallel to each other.

B) coating a thermoelectric film 20 of germanium on a part of a surface of each PVP sacrificing wire 10 by electron gun evaporation. The thickness of the thermoelectric films 20 can be controlled within the range of 80-200 nm by adjusting the coating rate and the coating time, in which the preferable coating rate is 0.5-2 Å/second. If the coating rate were lower than the prior range, the sacrificing wires might be over encapsulated by the thermoelectric films, resulting in higher difficulty of later removement of the sacrificing wires. On the other hand, if the coating rate were higher than the prior range, the coated film quality would become worse. Since the sacrificing wires 10 are adhered to the collecting bars 41 on one side, the thermoelectric films 20 are preferably coated on the other side of the sacrificing wires 10 and thus opposite to the collecting bars 41.

B2) transferring the sacrificing wires 10 each partially coated with the thermoelectric film 20 from the collector 40 to a substrate 50 in order to make the thermoelectric films 20 remain parallel to each other for later tests and applications. The substrate 50 can be coated with adhesive to adhere the thermoelectric films 20. Since there are more contacting areas between the substrate 50 and the thermoelectric films 20 than contacting areas between the collecting bars 41 and the sacrificing wires 10, the sacrificing wires 10 can be forced to depart from the collecting bars 41. As such, the thermoelectric films 20 are abutted against the substrate 50 on one side, and the sacrificing wires 10 are located on the other side of the thermoelectric films 20 and opposite to the substrate 50, in other words, the sacrificing wires 10 are exposed to the surroundings.

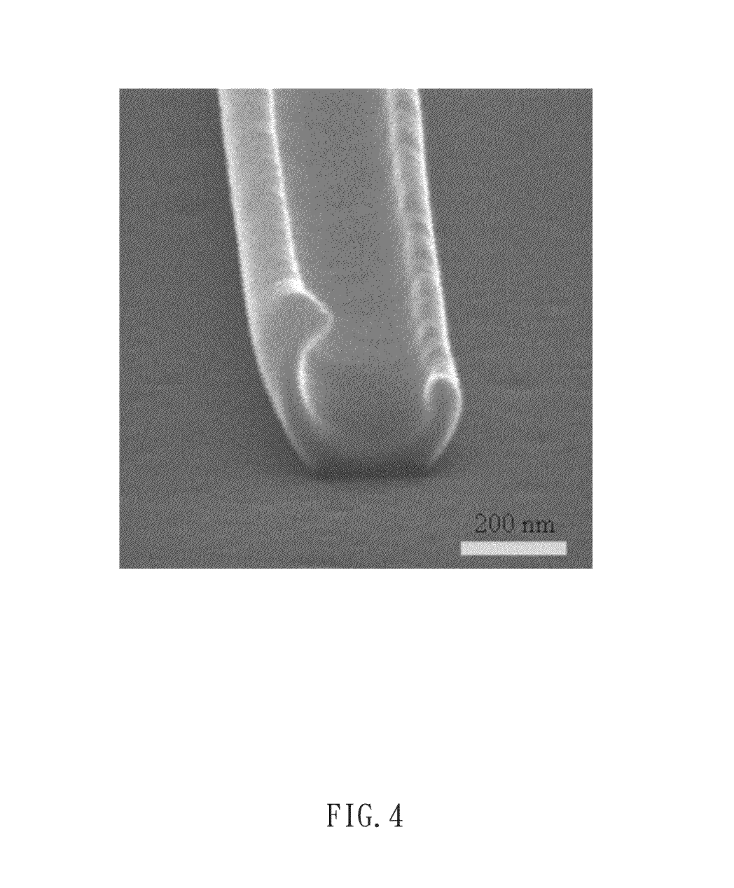

C) immersing the substrate 50 carrying the thermoelectric films 20 into an isopropanol solution for 8 hours to dissolve the sacrificing wires 10 therein. The thermoelectric films 20 are left on the substrate 50, each having a micro groove where the sacrificing wires 10 originally situated. The thickness of the thermoelectric films 20 in the preferred embodiment is about 80 nm, while the inner diameter thereof is about 300 nm. An SEM image of the prepared thermoelectric film is shown in FIG. 4.

In the aforementioned embodiment, the steps A2) and B2) are additional. included in order to keep the sacrificing wires and/or thermoelectric films parallel in steps B) and C), such that the finally prepared thermoelectric films are also parallel to each other for the convenience of later tests and applications. It is to be noted that steps A2) and B2) can be omitted in the present invention. Although it is preferable that the thermoelectric films are parallel to each other, it is not necessary to do so. And thus the thermoelectric films can also be randomly arranged in other possible embodiments of the present invention.

The invention described above is capable of many modifications, and may vary. Any such variations are not to be regarded as departures from the spirit of the scope of the invention, and all modifications which would be obvious to someone with the technical knowledge are intended to be included within the scope of the following

What is claimed is:

1. A method for forming a thermoelectric film having a micro groove, comprising the following steps:
A) forming a plurality of parallel sacrificing wires by electrospinning, a diameter of each sacrificing wire being 100-500 nm;
B) coating a thermoelectric film having a thickness of 80-200 nm on a part of a surface of each sacrificing wire; and
C) removing the sacrificing wires from the thermoelectric films and thus obtaining the thermoelectric films each having the micro groove, a radio side of each thermoelectric film being open to the surroundings.

2. The method of claim 1, wherein a lateral profile of each thermoelectric film having a half-rounded contour line which defines the micro groove.

3. The method of claim 1, wherein in the step A), a grounded metal plate is used to collect the sacrificing wires, the metal plate has a longitudinal slot formed thereon so that the sacrificing wires span the longitudinal slot laterally and are parallel to each other.

4. The method of claim 3, further comprising the following step between steps A) and B):
A2) collecting the sacrificing wires from the metal plate by a collector having two collecting bars, a distance between the collecting bars being smaller than a width of the longitudinal slot, the collected sacrificing wires spanning the collecting bars.

5. The method of claim 4, wherein in the step A2), the collecting bars are coated with adhesive, the collected sacrificing wires are adhered to the collecting bars.

6. The method of claim 5, wherein in the step B), each thermoelectric film is coating on a side of the respective sacrificing wire and opposite to the collecting bars.

7. The method of claim 6, further comprising the following step between the steps B) and C):
B2) transferring the sacrificing wires each partially coated with the thermoelectric film from the collector to a substrate, in which the thermoelectric films are abutted against the substrate on one side, the sacrificing wires are located on the other side of the thermoelectric films and opposite to the substrate.

8. The method of claim 7, wherein in the step B2), the substrate is coated with adhesive, the thermoelectric films are adhered to the substrate.

9. The method of claim 1, wherein in the step C), an organic solvent in which the sacrificing wires are dissolvable and the thermoelectric films are indissolvable is used to dissolve the sacrificing wires.

10. The method of claim 9, wherein the sacrificing wires are made from polyvinylpyrrolidone, and the organic solvent in the step C) is isopropyl alcohol.
